(19) United States
(12) Patent Application Publication
(10) Pub. No.: US 2018/0190943 A1
(43) Pub. Date: Jul. 5, 2018

(54) HIGH THERMAL CONDUCTIVE OLED DEVICE WITH HIGH REFRACTIVE INDEX

(71) Applicants: CHING-YAN CHAO, HSINCHU (TW); SHENG-YANG HUANG, HSINCHU (TW); FENG-WEN YEN, TAIPEI (TW)

(72) Inventors: CHING-YAN CHAO, HSINCHU (TW); SHENG-YANG HUANG, HSINCHU (TW); FENG-WEN YEN, TAIPEI (TW)

(73) Assignee: LUMINESCENCE TECHNOLOGY CORPORATION, HSINCHU (TW)

(21) Appl. No.: 15/649,662

(22) Filed: Jul. 14, 2017

(30) Foreign Application Priority Data
Jan. 5, 2017 (TW) 106100240

(51) Int. Cl. H01L 51/52

(52) U.S. Cl. CPC H01L 51/5281; H01L 51/529

(57) ABSTRACT

An OLED device is provided, which includes a substrate and a light emitting unit. The light emitting unit includes a first electrode, an organic material layer and a second electrode orderly arranged on the substrate. The other side of the substrate includes a micro-protrusion structure adhered to or integrally formed on the substrate; besides, the structure includes a plurality of micro-protrusion units, and each of the micro-protrusion units is orderly arranged to connect to the adjacent micro-protrusion units. The structure can adjust the light emitting angle and increase the luminance; further, the structure can reduce the energy consumption and decrease the influence from the thermal expansion and thermal contraction rates of the substrate, so the temperature increase during the OLED device being in operation can be significantly decreased to better the thermal dissipation rate thereof; therefore, the quality and the life thereof can be improved.

### BACKGROUND OF THE INVENTION

### 1. Field of the Invention

The present invention generally relates to a high thermal conductive OLED device with high refractive index.

### 2. Description of the Related Art

OLED is composed of two electrodes and an organic compound layer sandwiched by the electrodes; after the voltage is applied to the electrodes, the electrons and the holes will recombine in the organic compound layer to emit light. OLED is of high luminance, light in weight, extremely thin, self-lighting without backlight, of low power consumption, of wide view angle, of high contrast, easy to manufacture and of short response time, so is very suitable to be applied to flat panel display and the lighting industry.

According to currently available technologies, the substrate of most OLEDs is the glass substrate; however, after the light emitted by OLED enters the glass substrate and then passes through the glass substrate to enter the air, the total reflection phenomenon occurs because the light passes through the glass medium with higher refractive index and then enters the air medium with lower refractive index; accordingly, most (about 80%) of the light emitted by OLED will be confined in the substrate and the organic layer, and only 20% of which will enter the air.

For the purpose of solving the above problem, most of currently available technologies add a plastic optical film with micro-lens array to the other side of the substrate (the film may be adhered to or coated on the substrate), such as PET, which can change the light emitting angle to prevent from the total reflection phenomenon. The optical film can effectively better the overall luminous efficiency of OLED (about 60˜70%); however, as the OLED will generate additional thermal energy and the thermal conductive coefficient of the PET optical film is only 0.2 Wm⁻¹K⁻¹ which is lower than that (1.1˜1.4 Wm⁻¹K⁻¹) of the glass substrate, the additional thermal energy is hard to dissipate but keeps accumulating, which will influence the quality and life of OLED. Moreover, as the material of the optical film is different from that of the substrate, they also have different thermal expansion and thermal contraction rates; for the reason, the optical film will be finally separated from the substrate after the temperature has repeatedly increase and decrease for a long time, which will also influence the quality and life of OLED.

Accordingly, it has become an important issue to increase the overall luminous efficacy of OLED, and simultaneously improve the quality and the life thereof.

### SUMMARY OF THE INVENTION

To achieve the foregoing objective, the present invention provides a high thermal conductive OLED device with high refractive index, which mainly includes a substrate and a light emitting unit, wherein the refractive index of the substrate is 1.6˜2.8, and the thermal conductive index of the substrate is 30˜600 Wm⁻¹K⁻¹. The light emitting unit is disposed on one side of the substrate; the light emitting unit includes a first electrode, an organic material layer and a second electrode orderly arranged on the substrate. The other side of the substrate is provided with a micro-protrusion structure, and the micro-protrusion structure can be adhered to or integrally formed on the substrate; the micro-protrusion structure includes a plurality of micro-protrusion units, and each of the micro-protrusion units is orderly arranged to connect to the adjacent micro-protrusion units.

In a preferred embodiment of the present invention, the substrate is an aluminum oxide (Al₂O₃) substrate, the refractive index of the substrate is 1.6˜1.8, and the thermal conductive index of the substrate is 30˜60 Wm⁻¹K⁻¹; further, the substrate is a single-crystal aluminum oxide substrate or a multi-crystal aluminum oxide substrate.

In a preferred embodiment of the present invention, the substrate is a silicon carbide (SiC) substrate, and the refractive index of the substrate is 2.6˜2.8, and the thermal conductive index of the substrate is 300˜600 Wm⁻¹K⁻¹.

The present invention provides a high thermal conductive OLED device with high refractive index, which can simplify the structure of the OLED substrate; in addition, the micro-protrusion structure can further adjust the incident angle of the emitted light, so the emitted light will not be confined or absorbed by the substrate; in this way, the luminance of the OLED device can be increased and the power consumption thereof can also be reduced. Furthermore, compared with currently available technologies, the present invention can further reduce the influence from the thermal expansion and thermal contraction rates of the substrate by the micro-protrusion structure, so the temperature increase during the OLED device being in operation can be significantly decreased to better the thermal dissipation rate thereof; therefore, the quality and the life can be improved.

### BRIEF DESCRIPTION OF THE DRAWINGS

The detailed structure, operating principle and effects of the present invention will now be described in more details hereinafter with reference to the accompanying drawings that show various embodiments of the invention as follows.

FIG. 1 is a schematic view of an OLED device of an embodiment in accordance with the present invention.

FIG. 2 is a schematic view of an OLED device of another embodiment in accordance with the present invention.

FIG. 3 is a schematic view of an OLED device of still another embodiment in accordance with the present invention.

FIG. 4 is a luminance-yield relation diagram of the OLED device in accordance with the present invention.

FIG. 5 is a luminance-temperature relation diagram of the OLED device in accordance with the present invention.

FIG. 6 is a current density-temperature relation diagram of the OLED device in accordance with the present invention.

100 Substrate
200 Light emitting unit
210 First electrode
220 Organic material layer
230 Second electrode
300 Micro-protrusion structure
310 Micro-protrusion unit

### DETAILED DESCRIPTION OF THE PREFERRED EMBODIMENTS

The technical content of the present invention will become apparent by the detailed description of the following embodiments and the illustration of related drawings as follows.

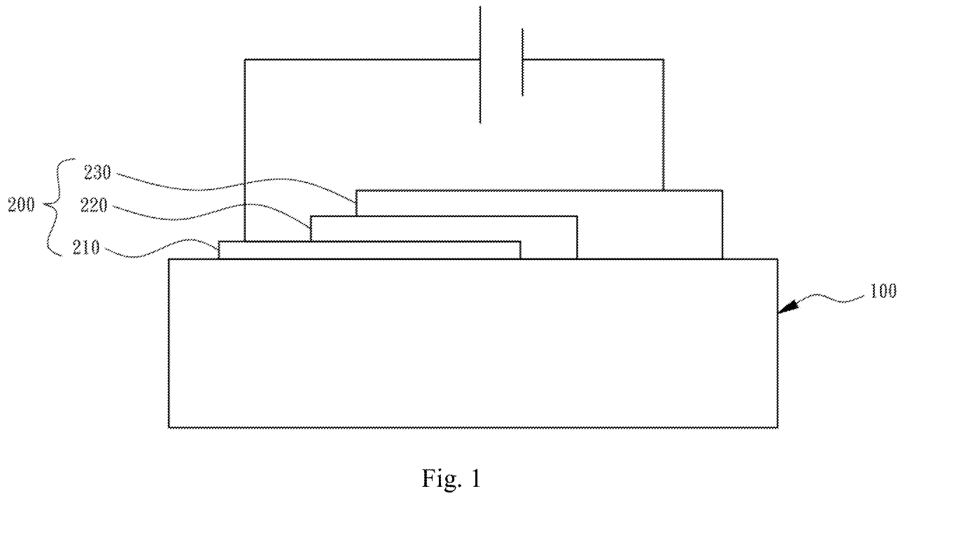

Please refer to FIG. 1, which is a schematic view of an OLED device of an embodiment in accordance with the present invention; as shown in FIG. 1, the OLED device mainly includes a substrate 100 and a light emitting unit 200. The refractive index of the substrate 100 is 1.6˜2.8, and the thermal conductive index of the substrate 100 is 30˜600 Wm⁻¹K⁻¹. The light emitting unit 200 is disposed on one side of the substrate 100; besides, the light emitting unit 200 includes a first electrode 210, an organic material layer 220 and a second electrode 230 orderly arranged on the substrate 100.

More specifically, the substrate 100 may be made of single-crystal aluminum oxide (Al₂O₃) or multi-crystal aluminum oxide; in addition, the refractive index of the Al₂O3 substrate 100 is 1.6˜1.8, and the thermal conductive index thereof is 30˜60 Wm⁻¹K⁻¹.

Alternatively, the substrate 100 may be made of silicon carbide (SiC); in addition, the refractive index of the silicon carbide substrate 100 is 2.6˜2.8, and the thermal conductive index thereof is 300˜600 Wm⁻¹K⁻¹.

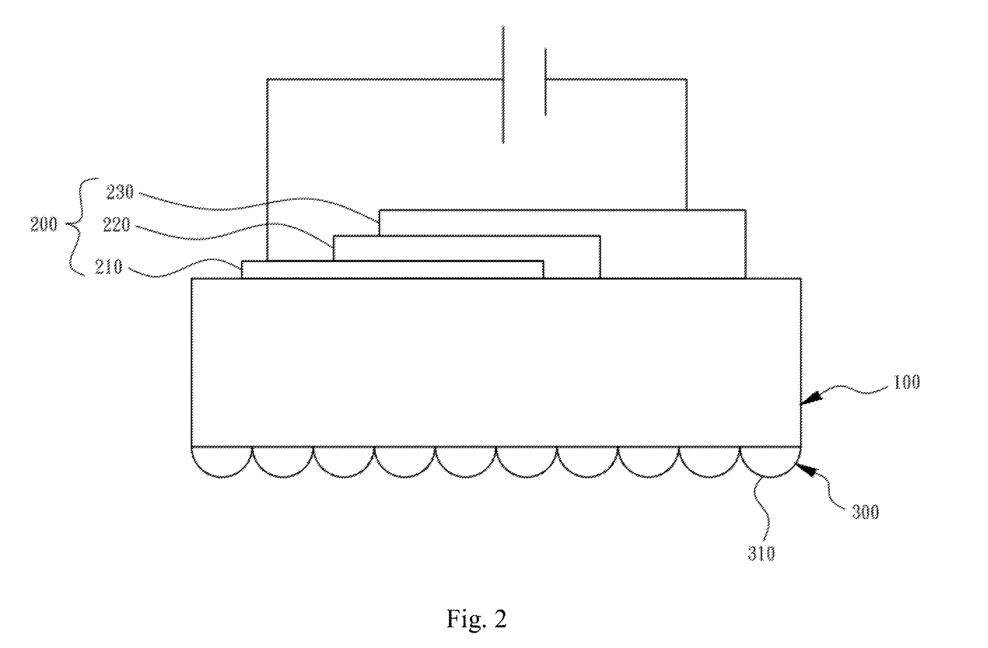

Please refer to FIG. 2, which is a schematic view of an OLED device of another embodiment in accordance with the present invention; as shown in FIG. 2, the OLED device mainly includes a substrate 100 and a light emitting unit 200. The refractive index of the substrate 100 is 1.6˜2.8, and the thermal conductive index of the substrate 100 is 30˜600 Wm⁻¹K⁻¹. The light emitting unit 200 is disposed on one side of the substrate 100; besides, the light emitting unit 200 includes a first electrode 210, an organic material layer 220 and a second electrode 230 orderly arranged on the substrate 100. Besides, the other side of the substrate 100 is provided with a micro-protrusion structure 300, and the micro-protrusion structure 300 includes a plurality of micro-protrusion units 310, and each of the micro-protrusion units 310 is orderly arranged to connect to the adjacent micro-protrusion units 310.

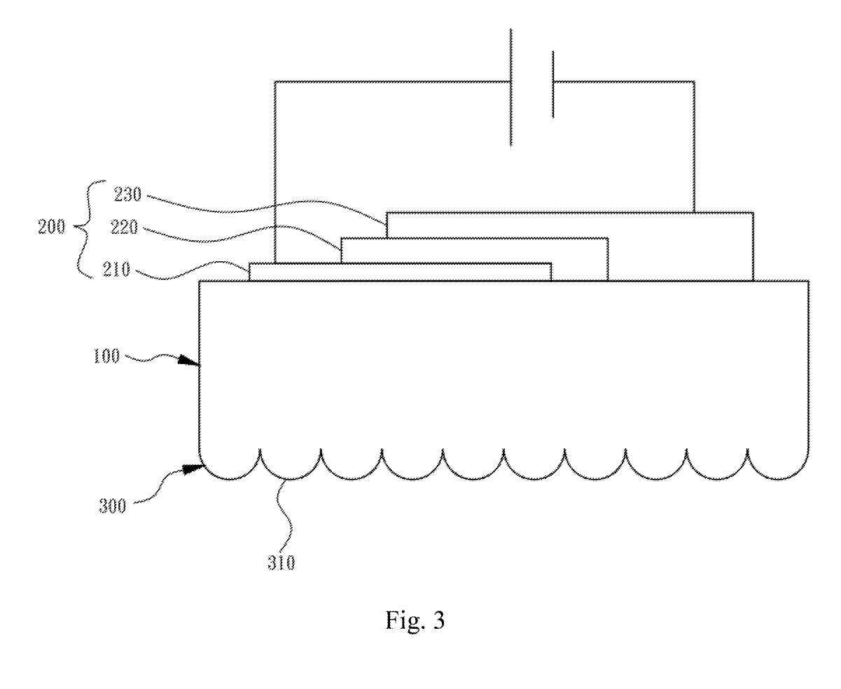

Please refer to FIG. 3, which is a schematic view of an OLED device of still another embodiment in accordance with the present invention; as shown in FIG. 3, the OLED device mainly includes a substrate 100 and a light emitting unit 200. The refractive index of the substrate 100 is 1.6˜2.8, and the thermal conductive index of the substrate 100 is 30˜600 Wm⁻¹K⁻¹. The light emitting unit 200 is disposed on one side of the substrate 100; besides, the light emitting unit 200 includes a first electrode 210, an organic material layer 220 and a second electrode 230 orderly arranged on the substrate 100. Besides, the other side of the substrate 100 is provided with a micro-protrusion structure 300, and the micro-protrusion structure 300 is integrally formed on the substrate 100; further, the micro-protrusion structure 300 includes a plurality of micro-protrusion units 310, and each of the micro-protrusion units 310 is orderly arranged to connect to the adjacent micro-protrusion units 310.

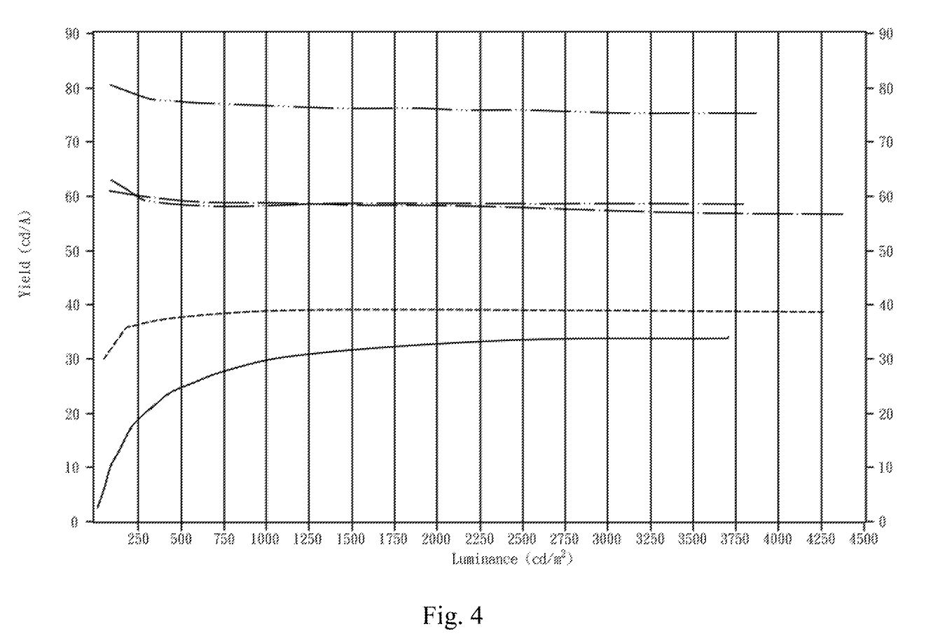

Please refer to FIG. 4, which is an luminance-yield relation diagram of the OLED device in accordance with the present invention, which shows the luminance-yield relation diagram of Reference group 1, Reference group 2 and Comparable groups 1˜3 of the OLED devices with different substrates and micro-protrusion structures. More specifically, Reference group 1 is the OLED device using the glass substrate (shown by real line); Reference group 2 is the OLED device using the aluminum oxide substrate (shown by dotted line); Comparable group 1 is the OLED device using the glass substrate with the micro-protrusion structure adhered to the substrate (shown by one-dot chain line); Comparable group 2 is the OLED device using the aluminum oxide substrate with the micro-protrusion structure adhered to the substrate (shown by two-dot chain line); Comparable group 3 is the OLED device using the aluminum oxide substrate with the micro-protrusion structure integrally formed on the substrate (shown by three-dot chain line). As shown in FIG. 4 and Table 1, the yield (cd/A) of Reference group 1 is about 33.7; the yield of Reference group 2 is about 38.6; the yield of Comparable group 1 is about 57.0; the yield of Comparable group 2 is about 58.7; the yield of Comparable group 3 is about 76.

TABLE 1

| | | Improvement |
|---|---|---|
| | Yield (cd/A) | ratio |
| Reference group 1 | 33.7 | N/A |
| Comparable group 1 | 57.0 | 69% |
| Comparable group 2 | 58.7 | 74% |
| Comparable group 3 | 76.0 | 126% |
| Reference group 2 | 38.6 | N/A |

As shown in FIG. 4 and Table 1, the yields of Comparable groups 1-3 are increased by 69%, 74% and 126% respectively when compared with Reference group 1. Accordingly, when compared with Reference group 1, the micro-protrusion structure of Comparable group 1 can increase the yield of the OLED device by 69%. When compared with Reference group 1, the micro-protrusion structure of Comparable group 2 can increase the yield of the OLED device by 74% since the substrate is made of aluminum oxide. When compared with Reference group 1, the micro-protrusion structure of Comparable group 3 can increase the yield of the OLED device by 126% since the aluminum oxide substrate and the micro-protrusion structure are integrally formed.

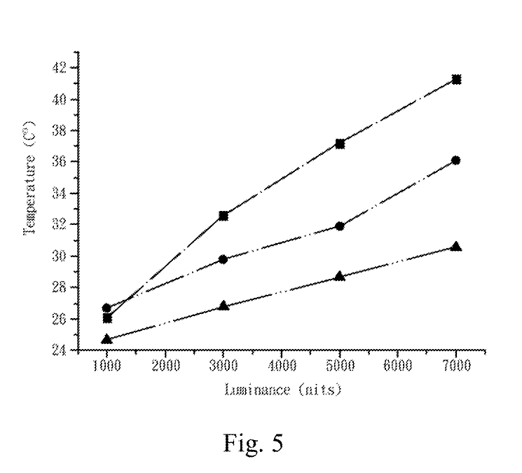

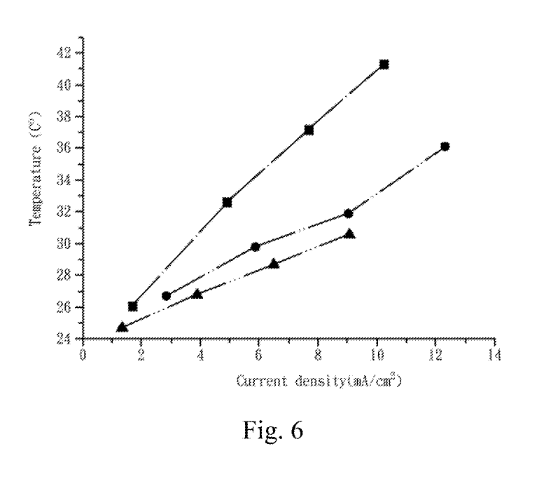

Please refer to FIG. 5 and FIG. 6, which are luminance, current density and temperature relation diagrams of the OLED device in accordance with the present invention, which show the luminance, current density and temperature relation diagrams of Reference group 1, Reference group 2 and Comparable groups 1˜3 of the OLED devices with different substrates and micro-protrusion structures. More specifically, Comparable group 1 is the OLED device using the glass substrate with the PET optical film having micro-protrusion structure adhered to the substrate (shown by one-dot chain line); Comparable group 2 is the OLED device using the aluminum oxide substrate with the PET optical film having the micro-protrusion structure adhered to the substrate (shown by two-dot chain line); Comparable group 3 is the OLED device using the aluminum oxide substrate with the micro-protrusion structure integrally formed on the substrate (shown by three-dot chain line).

As shown in FIG. 5 and Table 2, when the luminance (nits) of Comparable group 1 is 1000, 3000, 5000 and 7000, the corresponding the temperature of the OLED device is 26.1° C., 32.6° C., 37.2° C. and 41.3° C. respectively. When the luminance (nits) of Comparable group 2 is 1000, 3000, 5000 and 7000, the corresponding the temperature of the OLED device is 26.7° C., 29.8° C., 31.9° C. and 30.6° C. respectively. When the luminance (nits) of Comparable group 3 is 1000, 3000, 5000 and 7000, the corresponding the temperature of the OLED device is 24.7° C., 26.8° C., 28.7° C. and 30.6° C. respectively.

TABLE 2

| | Comparable | | Comparable | | Comparable | |
|---|---|---|---|---|---|---|
| | group 1 | | group 2 | | group 3 | |
| | J | Temper- | J | Temper- | J | Temper- |
| Luminance | (mA/ | ature | (mA/ | ature | (mA/ | ature |
| (nits) | cm²) | (° C.) | cm²) | (° C.) | cm²) | (° C.) |
| 1000 | 1.69 | 26.1 | 2.85 | 26.7 | 1.34 | 24.7 |
| 3000 | 4.91 | 32.6 | 5.87 | 29.8 | 3.91 | 26.8 |
| 5000 | 7.68 | 37.2 | 9.03 | 31.9 | 6.50 | 28.7 |
| 7000 | 10.22 | 41.3 | 12.32 | 36.1 | 9.07 | 30.6 |

As shown in FIG. 5 and Table 2, when the luminance (nits) is 7000, the temperature of the OLED device using the aluminum oxide substrate with the micro-protrusion structure integrally formed on the substrate (Comparable group 3) is obviously decreased by 10° C. when compared with the OLED device using the glass substrate with the PET optical film having micro-protrusion structure adhered to the substrate (Comparable group 1). For the reason, when the aluminum oxide substrate and the micro-protrusion structure are integrally formed to serve as the substrate of the OLED device, the OLED device can have lower working temperature; accordingly, the OLED device also has higher quality and longer life.

As shown in FIG. 6 and Table 2, when the temperature of the OLED device of Comparable group 1 is 26.1° C., 32.6° C., 37.2° C. and 41.3° C., the corresponding current density (J; mA/cm2) of the OLED device is about 1.69, 4.91, 7.68 and 10.22 respectively. When the temperature of the OLED device of Comparable group 2 is 26.7° C., 29.8° C., 31.9° C. and 36.8° C. the corresponding current density (J; mA/cm2) of the OLED device is about 2.85, 5.86, 9.03 and 12.23 respectively. When the temperature of the OLED device of Comparable group 3 is 24.7° C., 26.8° C., 28.7° C. and 30.6° C., the corresponding current density (J; mA/cm2) of the OLED device is about 1.34, 3.91, 6.50 and 9.07 respectively. According to FIG. 6 and Table 2, when the OLED devices are operated in the same current density, the OLED device using the aluminum oxide substrate with the micro-protrusion structure integrally formed on the substrate (Comparable group 3) has, compared with Comparable groups 1-2, highest luminance and lowest temperature.

Please refer to the following Table 3, which shows the life test result of Comparable group 1, Comparable group 2 and Comparable group 3.

TABLE 3

| | Comparable | Comparable | Comparable |
|---|---|---|---|
| Life test | group 1 | group 2 | group 3 |
| Luminance (0 hr) | 3000 nits | 3000 nits | 3000 nits |
| Luminance (450 hrs) | 2356 nits | 2453 nits | 2618 nits |
| Luminance (450 hrs)/ | 0.79 | 0.82 | 0.87 |
| Luminance (0 hr) | | | |

The present invention provides a high thermal conductive OLED device with high refractive index, which can simplify the structure of the OLED substrate; in addition, the micro-protrusion structure can further adjust the incident angel of emitted light, so the emitted light will not be confined or absorbed by the substrate; in this way, the luminance of the OLED device can be increased and the power consumption thereof can also be reduced; on the other hand, the OLED device can have lowest temperature under the same lighting condition, which can obviously improve the quality and the life of the OLED device.

While the means of specific embodiments in present invention has been described by reference drawings, numerous modifications and variations could be made thereto by those skilled in the art without departing from the scope and spirit of the invention set forth in the claims. The modifications and variations should in a range limited by the specification of the present invention.

1. A high thermal conductive OLED device with high refractive index, comprising:
a substrate, wherein a refractive index of the substrate is 1.6˜2.8, and a thermal conductive index of the substrate is 30˜600 Wm⁻¹K⁻¹; and
a light emitting unit, disposed at one side of the substrate, wherein the light emitting unit comprises a first electrode, an organic material layer and a second electrode orderly arranged on the substrate.

2. The OLED device of claim 1, wherein the other side of the substrate is provided with a micro-protrusion structure, and the micro-protrusion structure comprises a plurality of micro-protrusion units; each of the micro-protrusion units is orderly arranged to connect to the adjacent micro-protrusion units.

3. The OLED device of claim 2, wherein the micro-protrusion structure and the substrate are integrally formed.

4. The OLED device of claim 1, wherein the refractive index of the substrate is 1.6˜1.8, and the thermal conductive index of the substrate is 30˜60 Wm⁻¹K⁻¹.

5. The OLED device of claim 1, wherein the substrate is an aluminum oxide substrate.

6. The OLED device of claim 1, wherein the substrate is a signal-crystal aluminum oxide substrate.

7. The OLED device of claim 1, wherein the substrate is a multi-crystal aluminum oxide substrate.

8. The OLED device of claim 1, wherein the refractive index of the substrate is 2.6˜2.8, and the thermal conductive index of the substrate is 300˜600 Wm⁻¹K⁻¹.

9. The OLED device of claim 1, wherein the substrate is a silicon carbide substrate.
